(19) United States
(12) Patent Application Publication
(10) Pub. No.: US 2018/0351557 A1
(43) Pub. Date: Dec. 6, 2018

(54) METHOD AND APPARATUS FOR DYNAMIC ELECTRONIC CONTROL UNIT RECONFIGURATION

(71) Applicant: FORD GLOBAL TECHNOLOGIES, LLC, Dearborn, MI (US)

(72) Inventors: Gabriel JIM, Canton, MI (US); Jeffrey Raymond MOHR, Shelby Twp., MI (US); Yukiyasu NAGATA, Northville, MI (US); Michael J. IRBY, Monroe, MI (US); Hanyang B. CHEN, Canton, MI (US); Joseph Carl BEISER, Northville, MI (US)

(21) Appl. No.: 15/607,781

(22) Filed: May 30, 2017

(51) Int. Cl. H03K 19/173; H04W 4/04; G06F 17/30; G06F 17/50

(52) U.S. Cl. CPC H03K 19/1731; G06F 17/505; G06F 17/30038; H04W 4/046

(57) ABSTRACT

A system includes a processor configured to receive part identification input identifying a newly installed vehicle part. The processor is also configured to transmit part identification data to a cloud server, responsive to the input and receive electronic control unit (ECU) reconfiguration instructions responsive to the transmission. The processor is further configured to execute the instructions to reconfigure a vehicle ECU identified in the instructions.

### TECHNICAL FIELD

The illustrative embodiments generally relate to methods and apparatuses for dynamic electronic control unit reconfiguration.

### BACKGROUND

Aftermarket and customer installed replacement parts have existed in the automotive industry for years. There are thousands of custom parts that can be installed on different vehicles, and those parts improve the look or performance of a vehicle.

With many custom parts, it may have required a skilled mechanic to install the part and otherwise reconfigure the vehicle in order to optimize a performance gain. In many cases, a mechanic would not even know all of the achievable performance gain “tweaks” to make to a vehicle, and thus the utility of the part may have gone under realized.

With the advent of vehicle computers and electronic control units (ECUs), there are even more options for customizing and improving performance based on installation of particular parts. Unfortunately, this means that the mechanic must now be skilled in making mechanical, electrical and software tweaks. This also means that a mechanic must keep appraised of the availability and installation options related to the ECUs.

### SUMMARY

In a first illustrative embodiment, a system includes a processor configured to receive part identification input identifying a newly installed vehicle part. The processor is also configured to transmit part identification data to a cloud server, responsive to the input and receive electronic control unit (ECU) reconfiguration instructions responsive to the transmission. The processor is further configured to execute the instructions to reconfigure a vehicle ECU identified in the instructions.

In a second illustrative embodiment, a computer implemented method includes reconfiguring a vehicle ECU in accordance with reconfiguration instructions received from a remote source, the instructions received responsive to transmitting identification, of a newly installed vehicle part, from a vehicle computing system connected to the ECU.

In a third illustrative embodiment, a system includes a processor configured to receive part identification information from a vehicle computer, relating to a newly installed vehicle part. The processor is also configured to determine which electronic control units (ECU)s exist in the vehicle, the ECUs identified in optimization instructions that correlate to a part identified by the part identification. The processor is further configured to transmit the optimization instructions for the ECUs that exist in the vehicle, responsive to determining that the ECUs exist in the vehicle.

### BRIEF DESCRIPTION OF THE DRAWINGS

FIG. 1 shows an illustrative vehicle computing system;

FIG. 2 shows an illustrative example of a vehicle part-data reception process;

FIG. 3 shows an illustrative example of a cloud-based calibration process;

FIG. 4 shows an illustrative process for calibration of ECUs for an unknown part; and

FIG. 5 shows an illustrative example of a part-to-database addition process.

### DETAILED DESCRIPTION

As required, detailed embodiments are disclosed herein; however, it is to be understood that the disclosed embodiments are merely illustrative and may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the claimed subject matter.

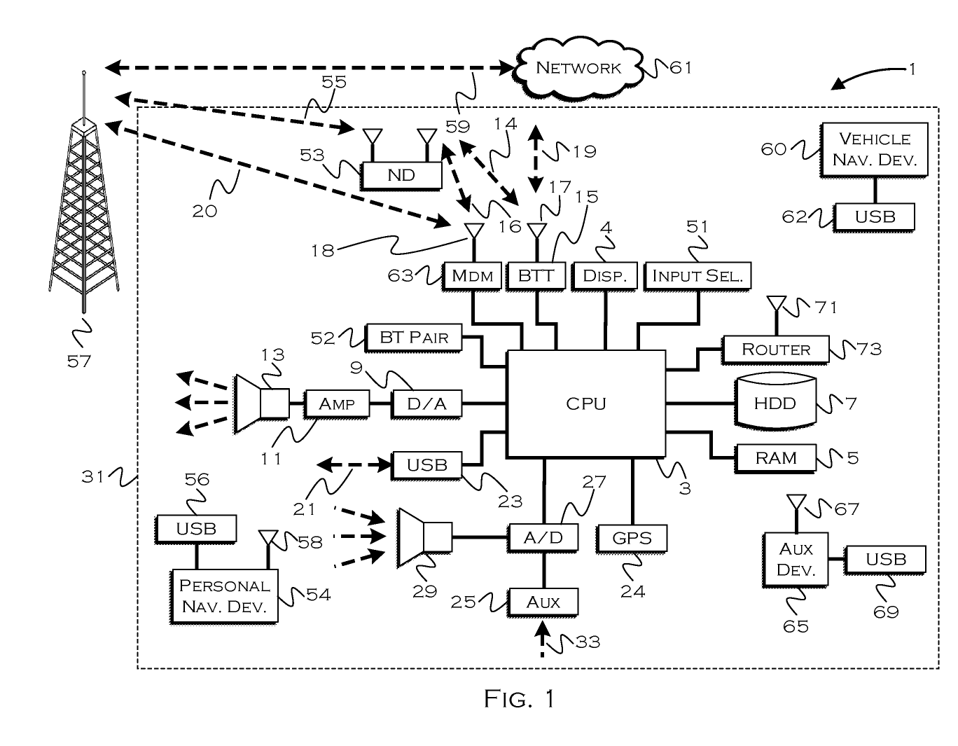

FIG. 1 illustrates an example block topology for a vehicle based computing system 1 (VCS) for a vehicle 31. An example of such a vehicle-based computing system 1 is the SYNC system manufactured by THE FORD MOTOR COMPANY. A vehicle enabled with a vehicle-based computing system may contain a visual front end interface 4 located in the vehicle. The user may also be able to interact with the interface if it is provided, for example, with a touch sensitive screen. In another illustrative embodiment, the interaction occurs through, button presses, spoken dialog system with automatic speech recognition and speech synthesis.

In the illustrative embodiment 1 shown in FIG. 1, a processor 3 controls at least some portion of the operation of the vehicle-based computing system. Provided within the vehicle, the processor allows onboard processing of commands and routines. Further, the processor is connected to both non-persistent 5 and persistent storage 7. In this illustrative embodiment, the non-persistent storage is random access memory (RAM) and the persistent storage is a hard disk drive (HDD) or flash memory. In general, persistent (non-transitory) memory can include all forms of memory that maintain data when a computer or other device is powered down. These include, but are not limited to, HDDs, CDs, DVDs, magnetic tapes, solid state drives, portable USB drives and any other suitable form of persistent memory.

The processor is also provided with a number of different inputs allowing the user to interface with the processor. In this illustrative embodiment, a microphone 29, an auxiliary input 25 (for input 33), a USB input 23, a GPS input 24, screen 4, which may be a touchscreen display, and a BLUETOOTH input 15 are all provided. An input selector 51 is also provided, to allow a user to swap between various inputs. Input to both the microphone and the auxiliary connector is converted from analog to digital by a converter 27 before being passed to the processor. Although not shown, numerous of the vehicle components and auxiliary components in communication with the VCS may use a vehicle network (such as, but not limited to, a CAN bus) to pass data to and from the VCS (or components thereof).

Outputs to the system can include, but are not limited to, a visual display 4 and a speaker 13 or stereo system output. The speaker is connected to an amplifier 11 and receives its signal from the processor 3 through a digital-to-analog converter 9. Output can also be made to a remote BLUETOOTH device such as PND 54 or a USB device such as vehicle navigation device 60 along the bi-directional data streams shown at 19 and 21 respectively.

In one illustrative embodiment, the system 1 uses the BLUETOOTH transceiver 15 to communicate 17 with a user's nomadic device 53 (e.g., cell phone, smart phone, PDA, or any other device having wireless remote network connectivity). The nomadic device can then be used to communicate 59 with a network 61 outside the vehicle 31 through, for example, communication 55 with a cellular tower 57. In some embodiments, tower 57 may be a WiFi access point.

Exemplary communication between the nomadic device and the BLUETOOTH transceiver is represented by signal 14.

Pairing a nomadic device 53 and the BLUETOOTH transceiver 15 can be instructed through a button 52 or similar input. Accordingly, the CPU is instructed that the onboard BLUETOOTH transceiver will be paired with a BLUETOOTH transceiver in a nomadic device.

Data may be communicated between CPU 3 and network 61 utilizing, for example, a data-plan, data over voice, or DTMF tones associated with nomadic device 53. Alternatively, it may be desirable to include an onboard modem 63 having antenna 18 in order to communicate 16 data between CPU 3 and network 61 over the voice band. The nomadic device 53 can then be used to communicate 59 with a network 61 outside the vehicle 31 through, for example, communication 55 with a cellular tower 57. In some embodiments, the modem 63 may establish communication 20 with the tower 57 for communicating with network 61. As a non-limiting example, modem 63 may be a USB cellular modem and communication 20 may be cellular communication.

In one illustrative embodiment, the processor is provided with an operating system including an API to communicate with modem application software. The modem application software may access an embedded module or firmware on the BLUETOOTH transceiver to complete wireless communication with a remote BLUETOOTH transceiver (such as that found in a nomadic device). Bluetooth is a subset of the IEEE 802 PAN (personal area network) protocols. IEEE 802 LAN (local area network) protocols include WiFi and have considerable cross-functionality with IEEE 802 PAN. Both are suitable for wireless communication within a vehicle. Another communication means that can be used in this realm is free-space optical communication (such as IrDA) and non-standardized consumer IR protocols.

In another embodiment, nomadic device 53 includes a modem for voice band or broadband data communication. In the data-over-voice embodiment, a technique known as frequency division multiplexing may be implemented when the owner of the nomadic device can talk over the device while data is being transferred. At other times, when the owner is not using the device, the data transfer can use the whole bandwidth (300 Hz to 3.4 kHz in one example). While frequency division multiplexing may be common for analog cellular communication between the vehicle and the internet, and is still used, it has been largely replaced by hybrids of Code Domain Multiple Access (CDMA), Time Domain Multiple Access (TDMA), Space-Domain Multiple Access (SDMA) for digital cellular communication. If the user has a data-plan associated with the nomadic device, it is possible that the data- plan allows for broad-band transmission and the system could use a much wider bandwidth (speeding up data transfer). In still another embodiment, nomadic device 53 is replaced with a cellular communication device (not shown) that is installed to vehicle 31. In yet another embodiment, the ND 53 may be a wireless local area network (LAN) device capable of communication over, for example (and without limitation), an 802.11g network (i.e., WiFi) or a WiMax network.

In one embodiment, incoming data can be passed through the nomadic device via a data-over-voice or data-plan, through the onboard BLUETOOTH transceiver and into the vehicle's internal processor 3. In the case of certain temporary data, for example, the data can be stored on the HDD or other storage media 7 until such time as the data is no longer needed.

Additional sources that may interface with the vehicle include a personal navigation device 54, having, for example, a USB connection 56 and/or an antenna 58, a vehicle navigation device 60 having a USB 62 or other connection, an onboard GPS device 24, or remote navigation system (not shown) having connectivity to network 61. USB is one of a class of serial networking protocols. IEEE 1394 (FireWire™ (Apple), i.LINK™ (Sony), and Lynx™ (Texas Instruments)), EIA (Electronics Industry Association) serial protocols, IEEE 1284 (Centronics Port), S/PDIF (Sony/Philips Digital Interconnect Format) and USB-IF (USB Implementers Forum) form the backbone of the device-device serial standards. Most of the protocols can be implemented for either electrical or optical communication.

Further, the CPU could be in communication with a variety of other auxiliary devices 65. These devices can be connected through a wireless 67 or wired 69 connection. Auxiliary device 65 may include, but are not limited to, personal media players, wireless health devices, portable computers, and the like.

Also, or alternatively, the CPU could be connected to a vehicle based wireless router 73, using for example a WiFi (IEEE 803.11) 71 transceiver. This could allow the CPU to connect to remote networks in range of the local router 73.

In addition to having exemplary processes executed by a vehicle computing system located in a vehicle, in certain embodiments, the exemplary processes may be executed by a computing system in communication with a vehicle computing system. Such a system may include, but is not limited to, a wireless device (e.g., and without limitation, a mobile phone) or a remote computing system (e.g., and without limitation, a server) connected through the wireless device. Collectively, such systems may be referred to as vehicle associated computing systems (VACS). In certain embodiments particular components of the VACS may perform particular portions of a process depending on the particular implementation of the system. By way of example and not limitation, if a process has a step of sending or receiving information with a paired wireless device, then it is likely that the wireless device is not performing that portion of the process, since the wireless device would not “send and receive” information with itself. One of ordinary skill in the art will understand when it is inappropriate to apply a particular computing system to a given solution.

In each of the illustrative embodiments discussed herein, an exemplary, non-limiting example of a process performable by a computing system is shown. With respect to each process, it is possible for the computing system executing the process to become, for the limited purpose of executing the process, configured as a special purpose processor to perform the process. All processes need not be performed in their entirety, and are understood to be examples of types of processes that may be performed to achieve elements of the invention. Additional steps may be added or removed from the exemplary processes as desired.

With respect to the illustrative embodiments described in the figures showing illustrative process flows, it is noted that a general purpose processor may be temporarily enabled as a special purpose processor for the purpose of executing some or all of the exemplary methods shown by these figures. When executing code providing instructions to perform some or all steps of the method, the processor may be temporarily repurposed as a special purpose processor, until such time as the method is completed. In another example, to the extent appropriate, firmware acting in accordance with a preconfigured processor may cause the processor to act as a special purpose processor provided for the purpose of performing the method or some reasonable variation thereof.

The illustrative examples leverage a vehicle's ability to connect to the cloud, in order to transmit part installation data and receive instructions on updating vehicle ECUs. The cloud resources can optimize, or predict optimized ECU settings for a particular aftermarket part. The cloud can send these configuration instructions to a vehicle computer, which can reconfigure the ECUs based on the instructions so that optimal or near optimal performance is achieved with the new part, at least from a computing perspective.

Part identification can be made through capture of a serial number, a manufacturer and/or model number, or even identification of the part type (e.g., brake pad) and a manufacturer. In some cases, it may also be useful to send part characteristics, which can be physical (e.g., carbon fiber), mechanical (e.g., 10,000 rpm), electrical (e.g., 5,000 volt) or even digital (e.g., software version 1.12).

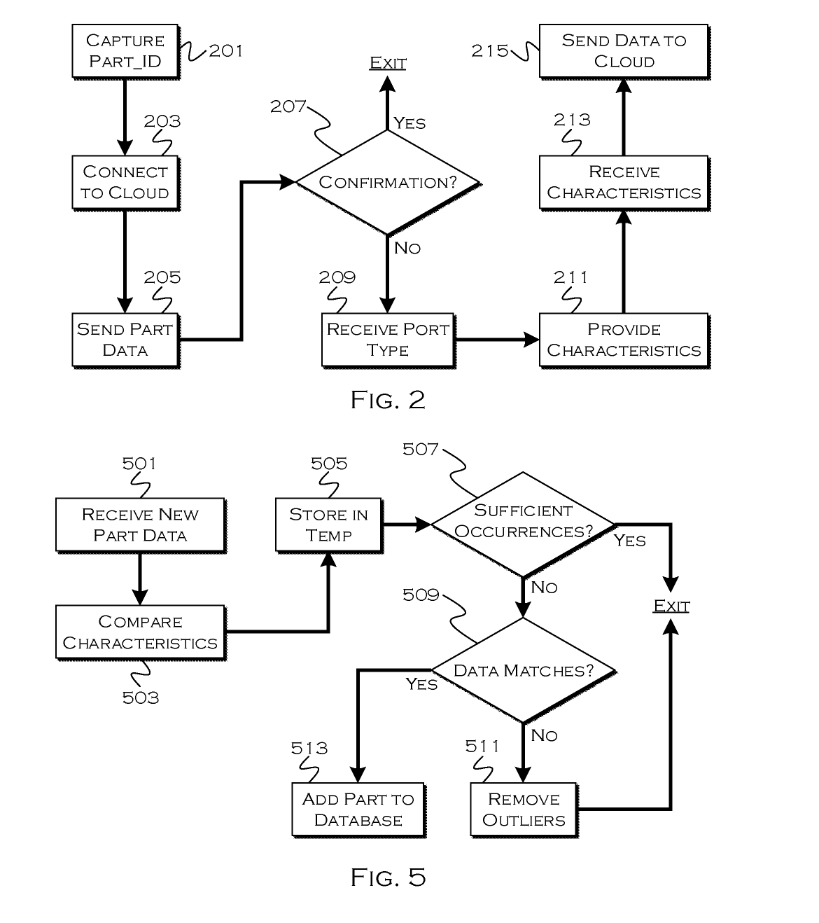

FIG. 2 shows an illustrative example of a vehicle part-data reception process. In this non-limiting example, a user/dealer/mechanic has installed a new part on a vehicle. This could be any sort of aftermarket or replacement part, and the functionality of the new part might be better realized if some recalibration of vehicle ECUs could occur.

It may be possible for a dealer or other skilled technician to review a list of ECUs calibrations or dynamically configure an ECU based on part specifications. This, however, could be a time consuming process, and may not take full advantage of the current level of knowledge about proper calibration, unless the technician also has that current level of knowledge. The illustrative example provides for automate recalibration based on a centralized database of knowledge, allowing known optimizations to be performed on ECUs quickly and efficiently, with assurances that the likely best calibration is the one being used.

In this example, the technician or user captures 201 a part ID. This could include, for example, scanning a SKU, photographing a part or part number, or otherwise inputting relevant part data (manufacturer ID, for example). If there is no available part identification, the technician might know the technical specifications of the part, from a manual or box, and be able to input those specification as the relevant part ID.

The process then connects 203 to the cloud and sends 205 the part ID or other data to the cloud. In this example, the process first attempts to collect the part information based on a part number or identification number. If the cloud confirms 207 knowledge of the particular part, the process will proceed to an optimization strategy discussed with respect to FIG. 3.

If the cloud is unaware of the part ID and cannot confirm knowledge of the part, the process may request some part specific data. This can include, for example, receiving 209 input of a part type (e.g., brake caliper). Based on an identified part type, the process may provide 211 a list of relevant characteristics which the user or technician can use as the basis to input part data.

For any characteristic fields that are known by the inputting user, the process may receive 213 the known characteristic data (e.g., material, electrical characteristics, etc.). The process can then send 215 this data to the cloud, where the cloud can respond to the characteristics, as well as build a record of the part for use in later requests for the same part.

FIG. 3 shows an illustrative example of a cloud-based calibration process. In this example, the cloud receives 301 a part identification input by a technician or user and transmitted to the cloud. The cloud then looks up 303 the part based on the identification, to determine if the part is already known 305 in a database of calibration characteristics.

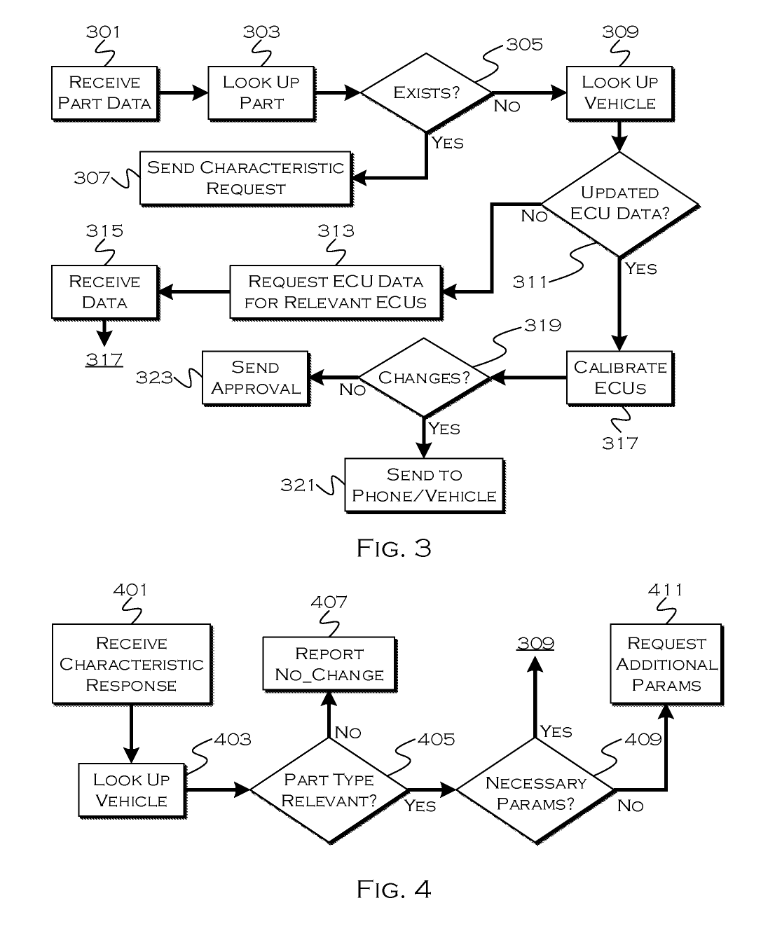

If the part is not currently known, the process may send a request 307 for part-specific characteristics, and receive those characteristics in response, before proceeding to the process defined in FIG. 4.

If the part is known, the process may also look up 309 or receive vehicle calibration data, indicating the current settings for any reconfigurable ECUs that might interact with the part or otherwise benefit from a recalibration in light of the part. If the lookup reveals 311 ECU calibration data that is older than a predetermined threshold time period, or otherwise may appear to be out of date, the process can send 313 a request to the vehicle for updated ECU data. The process receives 315 the updated ECU data responsive to this request. If the process had received the ECU data as part of the part-ID request, or at a previous point in the process, the process may forego this step.

Based on the updated ECU data or existing up-to-date ECU data, the process can then calibrate 317 the ECUs. This can be based on calibration equations defined for a particular ECU based on known part characteristics, and the effect that part has in interaction with the ECU, or the calibration could be based on predefined settings associated with a particular part or part characteristic for a particular vehicle or group of vehicles.

If the calibration of the ECUs results 319 in any changes, the process can send 321 recalibration instructions to a phone or vehicle. Sending the instructions to the phone, as well as the vehicle, may allow recalibration to take place at a time when the vehicle cannot otherwise access the recalibration system on the cloud. For example, if a recalibration cannot occur while a vehicle is moving, the process may queue the recalibration on a phone or vehicle, and at some future time the process may download/install the recalibration data when the vehicle is parked. Since the vehicle may be parked in a place where no remote signal is available, also having the data on the phone allows for local communication between the phone and vehicle to facilitate the recalibration.

FIG. 4 shows an illustrative process for calibration of ECUs for a unknown part. In this example, the process receives 401 characteristic data responsive to a characteristic input or request sent when a part ID was unavailable or unknown. The process again looks up 403 the vehicle, which was identified in the initial request or as part of a separate inquiry. Based on the identified vehicle and knowledge about the vehicle ECUS, the process determines 405 if the part of an identified type is even relevant from a recalibration standpoint. That is, if there is no recalibration data for a certain vehicle based on having new brake calipers installed, there is no need to further proceed with the inquiry. The process can report 407 no change needed, and exit.

Even if a change is not currently present, it may be later discovered that certain parts benefit from a previously unknown recalibration. Accordingly, it is possible to store a record of all the identified parts with respect to a particular vehicle, and the remote system can periodically run a check of the parts against current and improved ECU calibrations, to determine if a dynamic ECU recalibration should occur. If the system identifies an opportunity for recalibration, the system can request communication with the vehicle to send recalibration instructions.

If there is at least one possible recalibration relating to a part of the identified type, the process can determine 409 if parameters necessary for performing the recalibration are present. For example, if the process was informed that an unknown brake pad was installed, the process may need to know the pad composition in order to recalibrate one or more ECUs. This step allows the process to determine if the needed data is present. If there is sufficient data for recalibration, the process can proceed to step 309 of FIG. 3. Otherwise, the process can request 411 the needed parameters, including specifying which parameters are needed, and loop back to step 409 until the necessary parameters are present (or until he process times-out).

FIG. 5 shows an illustrative example of a part-to-database addition process. In this example, the process receives 501 part data (type, characteristics, etc.) to a previously unknown part, or to a part that is not yet permanently part of the database. The process may compare 503 the identified part characteristics to other temporarily or permanently stored part characteristics, to determine if there is a usable correspondence between the new part and a known or previously identified part.

The process also temporarily stores 505 the part and characteristics in a temporary database. If the part occurs 507 a threshold number of times in the temporary database, the system determines that the part is likely a relevant part worth warehousing in the permanent database, and the system checks the characteristics associated with the part to determine 509 if the data matches for all or most instances of the part in the temporary database. If there are too may outliers for sufficient matches (e.g., 40% of the data does not match, 60% does, the system removes 511 the outlying data and regroups the matching data as a separate part). Following regrouping, the system may again determine if sufficient data remains for permanent identification, and if sufficient data remains, the process should now determine that the characteristic data matches and the system can add 513 the part to the permanent database.

If the part ID is input, but simply unknown, the system can store the data temporarily based on the part ID. This makes for an easy classification of multiple data entries as corresponding to the same part.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined in logical manners to produce situationally suitable variations of embodiments described herein.

What is claimed is:

1. A system comprising:
a processor configured to:
receive part identification input identifying a newly installed vehicle part;
transmit part identification data to a cloud server, responsive to the input;
receive electronic control unit (ECU) reconfiguration instructions responsive to the transmission; and
execute the instructions to reconfigure a vehicle ECU identified in the instructions.

2. The system of claim 1, wherein the part identification input and the part identification data includes a part serial number input via a vehicle input.

3. The system of claim 1, wherein the part identification input and the part identification data includes a part image captured by a mobile device camera and transferred to a vehicle computer.

4. The system of claim 1, wherein the part identification input and the part identification data include a part name and manufacturer name.

5. The system of claim 1, wherein the processor is configured to:
receive indication from the cloud server that the vehicle part is unknown, responsive to the transmission.

6. The system of claim 5, wherein the processor is configured to:
receive a request for parameter input, defining part parameters for the vehicle part to be user-input;
display an input request including identification of the part parameters; and
transmit the part parameters to the cloud server, responsive to user input of the part parameters.

7. The system of claim 1, wherein the part identification data includes one or more user input part parameters.

8. The system of claim 7, wherein the part parameters include physical part-characteristics.

9. The system of claim 7, wherein the part parameters include mechanical part-characteristics.

10. The system of claim 7, wherein the part parameters include electrical part-characteristics.

11. The system of claim 7, wherein the part parameters include digital part-characteristics.

12. A computer implemented method comprising:
reconfiguring a vehicle ECU in accordance with reconfiguration instructions received from a remote source, the instructions received responsive to transmitting identification, of a newly installed vehicle part, from a vehicle computing system connected to the ECU.

13. The method of claim 12, wherein transmitting the identification includes transmitting a part serial number.

14. The method of claim 12, wherein transmitting the identification includes transmitting a part model number.

15. The method of claim 12, wherein transmitting the identification includes transmitting a part digital image.

16. The method of claim 12, wherein transmitting the identification includes transmitting part characteristics.

17. The method of claim 12, wherein transmitting the identification includes transmitting a part type and manufacturer name.

18. A system comprising:
a processor configured to:
receive part identification information from a vehicle computer, relating to a newly installed vehicle part;
determine which electronic control units (ECU)s exist in a vehicle, the ECUs identified in optimization instructions that correlate to a part identified by the part identification information; and
transmit the optimization instructions for the ECUs that exist in the vehicle, responsive to determining that the ECUs exist in the vehicle.

19. The system of claim 18, wherein the processor is configured to determine which ECUs exist in the vehicle based on a vehicle configuration stored in a cloud server.

20. The system of claim 18, wherein the processor is configured to determine which ECUs exist in the vehicle based on a vehicle configuration received with the part identification information.
